(19) United States
(12) Patent Application Publication
(10) Pub. No.: US 2025/0323615 A1
(43) Pub. Date: Oct. 16, 2025

(54) POST-RESONANCE CIRCUITS, DEVICES, SYSTEMS, AND METHODS

(71) Applicant: Cornell University, Ithaca, NY (US)

(72) Inventors: Bala Govind, Ithaca, NY (US); Alyssa Apsel, Ithaca, NY (US)

(21) Appl. No.: 19/178,187

(22) Filed: Apr. 14, 2025

Related U.S. Application Data
(60) Provisional application No. 63/633,380, filed on Apr. 12, 2024.

(51) Int. Cl. H03H 7/20; H01P 1/18; H03H 7/01; H03H 7/075

(52) U.S. Cl. CPC H03H 7/20; H01P 1/182; H03H 7/075; H03H 7/175

(57) ABSTRACT

Illustrative embodiments of high-resolution, low-loss phase shifting circuits, devices, systems, and methods are disclosed. According to one aspect, a circuit may include a signal reflector that has a signal port configured to receive a signal in a signal frequency range and a resonant structure coupled between the signal port and ground. The resonant structure has one or more primary resonant frequencies and a cutoff frequency above the one or more primary resonant frequencies. The cutoff frequency is below the signal frequency range of the signal applied to the signal port.

### CROSS-REFERENCE TO RELATED APPLICATION

This application claims the benefit of U.S. Provisional Patent Application No. 63/633,380, filed Apr. 12, 2024, the entire disclosure of which is incorporated herein by reference.

### BACKGROUND

Today's wireless communication relies on electronic devices transmitting pencil-thin beams of microwave radiation to one another. This requires precise phase control of many signals that constructively interfere at specific points in space. For decades, achieving even modest phase-shifting resolution has demanded a complex mix of microwave switches and passive electromagnetic structures. These circuits operate near resonances that heavily attenuate and distort signals, limiting transmission bandwidth. Despite numerous attempts, passive phase shifters have remained lossy and incompatible with high-channel-capacity beamforming, irrespective of the semiconductor fabrication process.

### SUMMARY

According to one aspect, a circuit may comprise a first signal reflector that has a first signal port configured to receive a signal in a signal frequency range used for communication or computation and a first resonant structure coupled between the first signal port and ground. The first resonant structure has one or more primary resonances that interact to form one or more hybrid resonances and a cutoff frequency above resonant frequencies of the primary and hybrid resonances. The cutoff frequency is below the signal frequency range. The first resonant structure may be tunable to adjust the primary resonant frequencies.

In some embodiments, the first resonant structure comprises a segmented waveguide and tunable capacitances coupling each junction of the segmented waveguide to ground. In some embodiments, each segmented waveguide includes at least three waveguide segments. In some embodiments, each tunable capacitance is digitally programmable. In other embodiments, the circuit further comprises vacatur diodes configured to tune the tunable capacitances.

In some embodiments, each junction of the segmented waveguide is coupled to ground by a programmable capacitor bank comprising a plurality of parallel legs coupled between one junction of the segmented waveguide and ground, with each of the plurality of parallel legs comprising a capacitor and a switch coupled in series.

In some embodiments, the circuit is implemented as an integrated circuit such that the first signal reflector has a sub-wavelength footprint. In some embodiments, the segmented waveguide is formed as a conductive trace in an upper layer of the integrated circuit, and each tunable capacitance is formed in lower layers of the integrated circuit.

In some embodiments, the circuit further comprises a second signal reflector and a hybrid coupler. The second signal reflector may comprise a second signal port configured to receive the signal in the signal frequency range and a second resonant structure coupled between the second signal port and ground. The second resonant structure may have one or more primary resonances that interact to form one or more hybrid resonances and a cutoff frequency above resonant frequencies of the primary and hybrid resonances, where the cutoff frequency is below the signal frequency range. The hybrid coupler may have an input port configured to receive the signal in the signal frequency range, a coupled port connected to the first signal port of the first signal reflector, a through port connected to the second signal port of the second signal reflector, and an output port configured to provide a phase-shifted copy of the signal.

In some embodiments, an amount of phase shift between the signal and the phase-shifted copy of the signal is controllable in increments of less than 1 degree with less than 10 dB of loss. In some embodiments, the amount of phase shift between the signal and the phase-shifted copy of the signal is controllable in increments of less than 0.2 degrees with less than 5 dB of loss.

In some embodiments, the circuit is implemented as an integrated circuit such that the first signal reflector, the second signal reflector, and the hybrid coupler have a sub-wavelength footprint. In some embodiments, the first signal reflector, the second signal reflector, and the hybrid coupler do not consume DC power.

According to another aspect, a method may comprise tuning resonant frequencies of a resonant structure coupled between a signal port and ground, where the resonant frequencies are associated with one or more primary resonances of the resonant structure that interact to form one or more hybrid resonances, and where the resonant structure has a cutoff frequency above resonant frequencies; applying, to the signal port, a communication or computation input signal having a signal frequency above the cutoff frequency; and receiving, at the signal port, a reflected signal with a phase shift relative to the communication or computation input signal, where the phase shift is a function of the resonant frequencies of the resonant structure.

In some embodiments, the resonant frequencies of the resonant structure are tunable to adjust the phase shift in increments of less than 1 degree with less than 10 dB of loss between the communication or computation input signal and the reflected signal. In some embodiments, the resonant frequencies of the resonant structure are tunable to adjust the phase shift in increments of less than 0.2 degrees with less than 5 dB of loss between the communication or computation input signal and the reflected signal.

In some embodiments, the resonant structure comprises a segmented waveguide and tunable capacitances coupling each junction of the segmented waveguide to ground, and tuning the resonant frequencies of the resonant structure comprises tuning one or more of the tunable capacitances. In some embodiments, each of the tunable capacitances comprises a plurality of parallel legs coupled between one junction of the segmented waveguide and ground, with each of the plurality of parallel legs comprising a capacitor and a switch coupled in series, and tuning one or more of the tunable capacitances comprises switching one or more switches of the plurality of parallel legs. In other embodiments, tuning one or more of the tunable capacitances comprises controlling one or more varactor diodes.

### BRIEF DESCRIPTION OF THE DRAWINGS

The detailed description particularly refers to the following figures, in which:

FIG. 1 shows one illustrative embodiment of a reflective type phase shifter circuit;

FIG. 2 is a simplified circuit diagram of one of the multi-resonance reflectors of FIG. 1, tuned to produce a smaller phase shift;

FIG. 3 is a simplified circuit diagram of the multi-resonance reflector of FIG. 2, tuned to produce a larger phase shift;

FIG. 4 is a graph of reflectivity versus frequency for the multi-resonance reflector of FIG. 2;

FIG. 5 is a graph of phase shift versus frequency for the multi-resonance reflector of FIG. 2;

FIG. 6 is a photograph of an illustrative embodiment of the reflective type phase shifter circuit of FIG. 1 implemented in a Complementary Metal Oxide Semiconductor (CMOS) platform;

FIG. 7 includes graphs showing the insertion loss and absolute phase behaviors of the illustrative CMOS phase shifter circuit of FIG. 6;

FIG. 8 is a graph showing the insertion loss achieved by the illustrative CMOS phase shifter circuit of FIG. 6 in its post-resonance frequency spectrum;

FIG. 9 is a graph showing the return loss achieved by the illustrative CMOS phase shifter circuit of FIG. 6 in its post-resonance frequency spectrum;

FIG. 10 is a graph comparing average insertion loss versus phase tuning resolution for the present disclosure (“Post-Resonance Reflection”) and for several prior art systems (“All-Pass Networks,” “Tunable Transmission Line,” “Switched GaAs filters,” “Switched CMOS filters,” and “Passive Vector Modulation”); and

FIG. 11 is a graph comparing array factor versus broadside firing angle for the present disclosure (“Post Resonance Tuning”) and for several prior art systems (“All-pass Networks,” “Switched Filters,” and “Vector Modulation”).

### DETAILED DESCRIPTION

While the concepts of the present disclosure are susceptible to various modifications and alternative forms, specific illustrative embodiments thereof have been shown by way of example in the drawings and will herein be described in detail. It should be understood, however, that there is no intent to limit the concepts of the present disclosure to the particular forms disclosed, but on the contrary, the intention is to cover all modifications, equivalents, and alternatives falling within the spirit and scope of the invention as defined by the appended claims.

References in the specification to “one embodiment,” “an embodiment,” “an illustrative embodiment,” etc., indicate that the embodiment described may include a particular feature, structure, or characteristic, but every embodiment may or may not necessarily include that particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described. Additionally, it should be appreciated that items included in a list in the form of “at least one A, B, and C” can mean (A); (B); (C); (A and B); (A and C); (B and C); or (A, B, and C). Similarly, items listed in the form of “at least one of A, B, or C” can mean (A); (B); (C); (A and B); (A and C); (B and C); or (A, B, and C).

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the illustrative figures. Additionally, the inclusion of a structural or method feature in a particular figure is not meant to imply that such feature is required in all embodiments and, in some embodiments, may not be included or may be combined with other features.

The present disclosure teaches an approach whereby waveguide reflectors based on coupled resonances can be reprogrammed to evade loss. Specifically, in the presently disclosed approach, loss from resonances is confined to lower frequencies, while at higher frequencies, their reflectivity is maximized and broadband phase variations, induced by those resonances, persist. Since performance in this low-loss post-resonance spectrum is largely agnostic to the number of tuning switches, ultra-fine digital tuning is possible. This breaks the historical tradeoff between loss and precision to achieve resolution surpassing state-of-the-art electronics by over three orders of magnitude. The circuit does not distort the transmitted signal and consumes no DC power. Moreover, the illustrative embodiment's reflective-type phase-shifting structure occupies a sub-wavelength footprint in a Complementary Metal Oxide Semiconductor platform. This makes it an optimal candidate for seamless integration in on-chip transceiver arrays for multi-gigabit data links and in applications like radio astronomy and control electronics for millimeter-wave qubits.

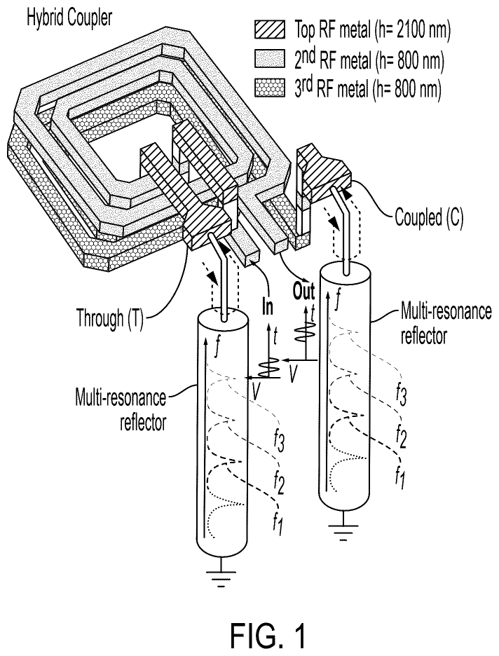

One illustrative embodiment of a reflective type phase shifter circuit, often used in passive microwave delay elements, is shown in FIG. 1. In use, a microwave signal is injected into the Input port of a quadrature hybrid coupler of the circuit, which splits the signal into two components with a 90° phase shift between them. These half-power components reflect off of tunable reflectors at the Through (T) and Coupled (C) ports of the coupler and then add at its Output port with a common phase shift. In this embodiment, the coupler has a miniature size since it is implemented on two metal layers as overlapping coils of a transformer (as compared to wavelength-scale transmission lines). While many different structures can be used for tunable reflector in this circuit, one that is maximally reflective and induces large phase shift is desirable. This phase shift can be achieved by resonance behavior, i.e., delay is induced during the reciprocal exchange of energy between electric and magnetic fields in the resonant reflector inserted on the coupler's ports. However, the resonance induces a swift phase shift only within a narrow frequency band. Beyond this band, a substantial portion of the signal is absorbed by the reflector, leaving little to be reflected.

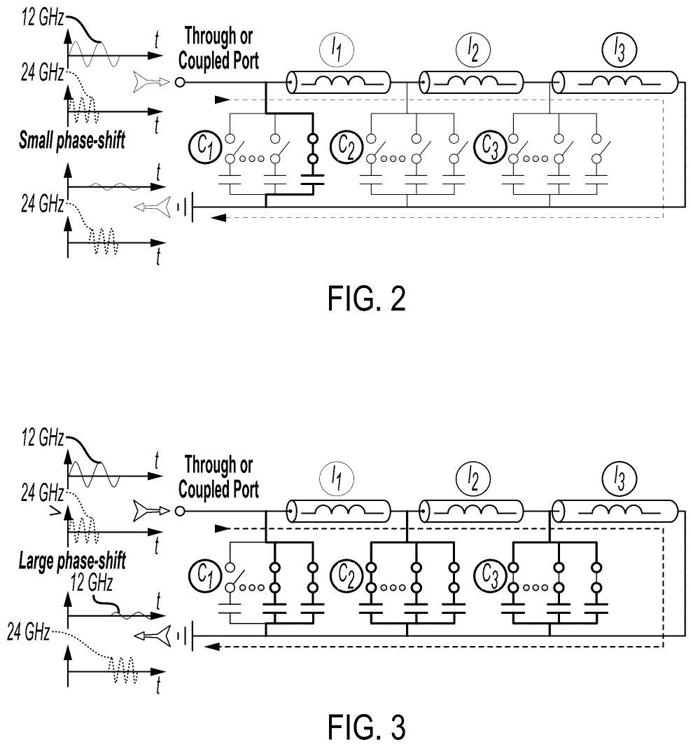

Instead of optimizing for a narrow resonant band, the present disclosure utilizes the resonance(s) differently. In this illustrative embodiment, each tunable reflector comprises a plurality of waveguide segments, with the final segment connected to ground to complete a return path for the microwave signal, as shown in FIGS. 2-3. (In one alternative embodiment, the final segment of each tunable reflector may be a true time delay.) Each waveguide segment is primarily inductive in nature. In addition, tunable capacitors are inserted intermittently at the junctions of these segments, resembling a “traveling wave” structure formed of a non-uniform waveguide whose impedance can be changed internally by varying these capacitors. The π-shaped sections of waveguide segments and capacitors couple with one another to form multiple hybrid resonances. These induce programmable phase delays corresponding to the selectable values of the tunable capacitances. Smaller capacitances (achieved by activating relatively fewer capacitors using their corresponding switches) lead to fewer pronounced resonances and give smaller phase shifts, as illustrated in FIG. 2. Larger capacitances (achieved by activating relative more capacitors in the banks) produce multiple strong, coupled resonances that impart large phase shifts, as illustrated in FIG. 3. Since the segmented, non-uniform transmission line is a waveguide, there exists an upper frequency limit (f_{cutoff}) beyond which no signal can propagate down its length, akin to the Bragg periodic cutoff frequency. This broadband structure best suits a reflective-type delay element since it would be maximally reflective beyond this frequency.

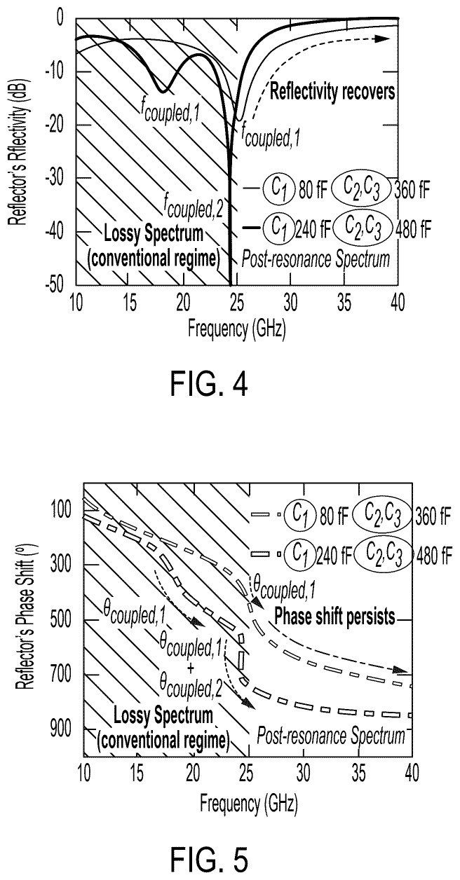

The tunable capacitor-loaded waveguide segments shown in FIGS. 2-3 produce numerous lossy, coupled resonances below the cutoff frequency. Within this frequency range, fluctuations in the fraction of signal reflected from these waveguides occur. Additionally, these resonances generate broad dips in the amplitude response of the reflection coefficient, as shown in FIG. 4. In Complementary Metal Oxide Semiconductor (CMOS) process technologies, this is expected because of the poor quality-factors of the circuit components that created them. If the composite phase shifter were designed using a conventional approach that only used the phase shift within the band(s) surrounding these resonance(s), significant loss would occur. Instead, the present disclosure utilizes the ultra-broadband spectrum above the cutoff frequency and above the resonant frequencies of the primary and hybrid resonances of the reflective waveguide (referred to herein “post-resonance”).

As illustrated in FIG. 5, the phase response of the reflection coefficient reveals the advantage of the multiple lossy resonances. Tuning the natural resonant frequencies (f₁, f₂, . . . fₙ) of the cascade of resonators comprising the reflector modulates the positions of the coupled resonances (f_{coupled,1}, f_{coupled,2}, . . . f_{coupled,n}) in the spectrum, thereby determining where the recovery in reflection coefficient begins. While the magnitude of the reflection coefficient simply experiences dips and recoveries within finite bandwidths around each resonance, a phase shift is accumulated after each coupled resonance. Consequently, beyond the last resonance (about 20 GHz in this embodiment), the reflecting waveguides transmit no signal but only impart tunable, cumulative and broadband phase shifts. Essentially, isolating lossy resonances at lower frequencies enables the use of as many switches as needed to achieve the desired resolution of phase tuning. This is possible because although each switch contributes to a signal-absorbing resonance, this local behavior is immaterial since the device is not operated at these lower frequencies but rather in the higher post-resonance spectrum.

The finite quality factors of the switches manifest as internal dissipation rates, aiding in coupling resonators of different natural frequencies and facilitating a gradual transition in the phase curves between coupled resonances. This transition results in a distinct roll-off beyond the highest coupled resonance frequency for each digitally tuned phase state. Specifically, when activated or deactivated, the switches alter the decay rates of the coupled modes in the multi-resonant waveguide, thereby tuning the ultra-broadband phase shift. At extremely high frequencies (e.g., beyond 200 GHz), the phase curves gradually converge asymptotically, causing the reflector to behave akin to a short circuit to ground. Nonetheless, for all practical purposes, a near-constant phase shift is achieved across tens of gigahertz within the band.

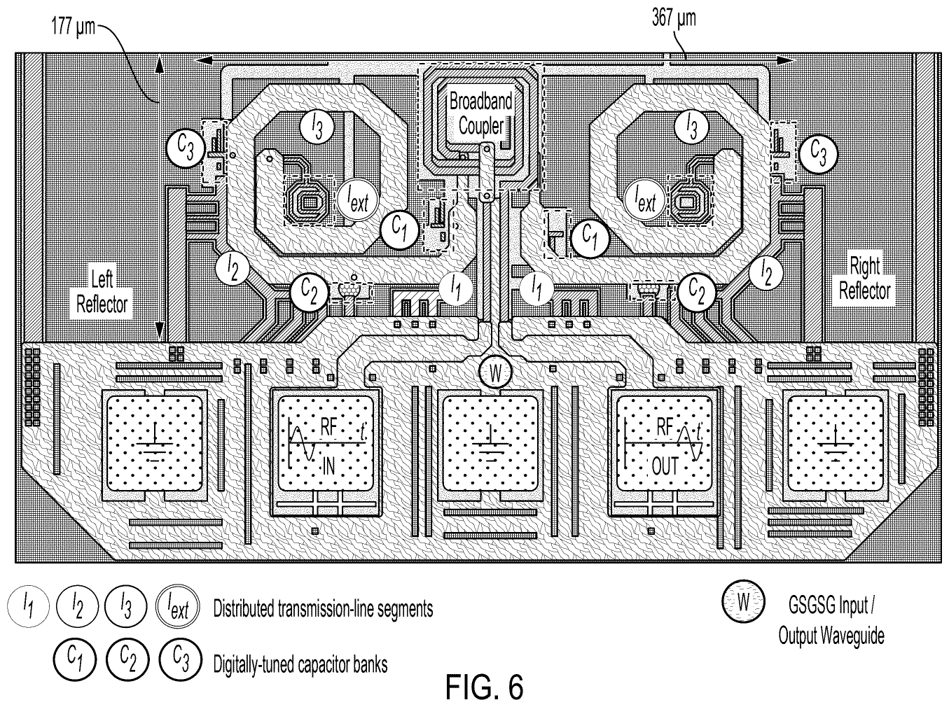

An illustrative embodiment of the reflective type phase shifter circuit of FIG. 1, including the two tunable reflectors illustrated in FIGS. 2-3, was fabricated on a Fully Depleted Silicon-on-Insulator 28 nanometer CMOS platform, within an area of only 0.064 mm² of silicon. A photograph of this illustrative embodiment is shown in FIG. 6. In this technology, the leakage of electromagnetic field from the passive structures to the substrate is negligible, sustaining performance at millimeter-wave frequencies. The hybrid coupler and the waveguide segments of the tunable reflectors in this embodiment were constructed from coiled traces in three metal layers of the CMOS stack, resulting in an ultra-compact form factor. The digitally tuned capacitors of the reflectors were implemented as five-bit capacitor banks. Each capacitor bank, in turn, comprised several parallel legs of N-type Metal Oxide Semiconductor switches that brought metal-oxide-metal capacitors in or out of action. The input and output ports of the full device were accessed through a Ground-Signal-Ground-Signal-Ground (GSGSG) waveguide. This chip was designed to operate in the 5G New Radio spectrum for Multiple-Input-Multiple-Output (MIMO) communications.

In the illustrative embodiment of FIG. 6, to limit the total tuning bits to ten, capacitor banks C2 and C3 were digitally tuned to identical values (i.e., C2=C3) for every phase-state. Further, the discrete inductor lₑₓₜ is simply an appendage of the waveguide segment l₃ that helps boost the phase tuning range beyond 180°. Therefore, tuning the five-bit capacitor bank C1 inserted close to the beginning of the waveguide and the two other five-bit capacitor banks downstream (equal to C2) determines the frequency at which the last resonance occurs and, thereby, where the recovery in insertion loss begins. This approach represents a departure from the capabilities of conventional microwave electronics since, normally, using ten or more switches in a tunable impedance would prohibitively distort and weaken a signal. Although the illustrative embodiment of FIG. 6 was implemented in a CMOS platform, it will be appreciated by those skilled in the art that a similar integrated could be fabricated in other semiconducting platforms (e.g., GaN), or even superconducting platforms. In still other embodiments, circuits according to the present disclosure may be implemented with discrete components (rather than in an integrated circuit).

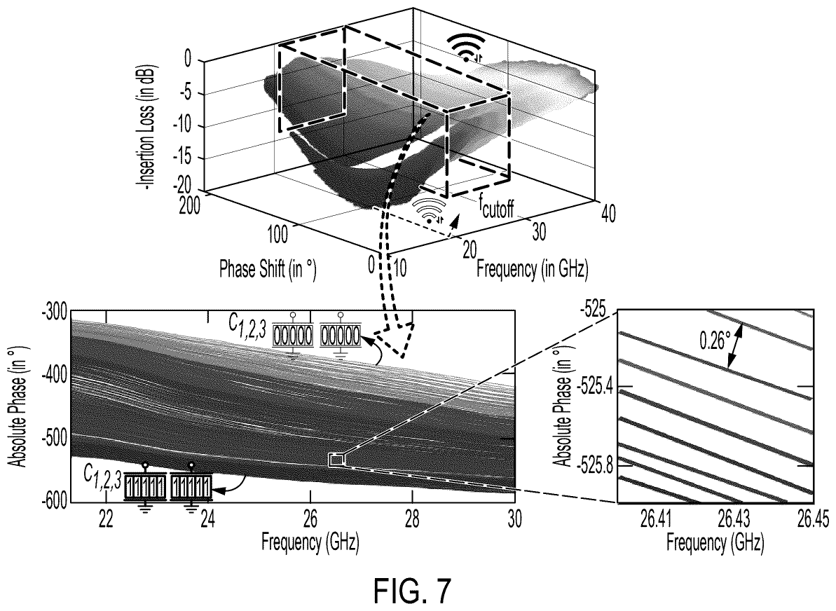

FIG. 7 shows the spread of both insertion loss and phase tuning for over 800 measured states of the phase shifter of FIG. 6. Loss recovered beyond the sub-20 GHz band for all states. This is because the frequency of 20 GHz is close to the cutoff frequency of the reflective waveguides, beyond which no transmission can occur, and the signal is reflected back. In this post-resonance regime, the loads on the Through and Coupled ports exhibit maximal reflectivity. Focusing on the 20-30 GHz frequency range, the presently disclosed post-resonance approach produced over 200° of phase tuning (see lower left detail in FIG. 7) with an ultra-fine phase resolution of under 0.3° (see lower right detail in FIG. 7) across the 20-30 GHz band. In practice, if more than 360° was required, a simple phase-flip circuit could be included. Additionally, the range and resolution of the circuit can be further improved, if needed, by altering the length of the final transmission line segment and by adding a true-time-delay.

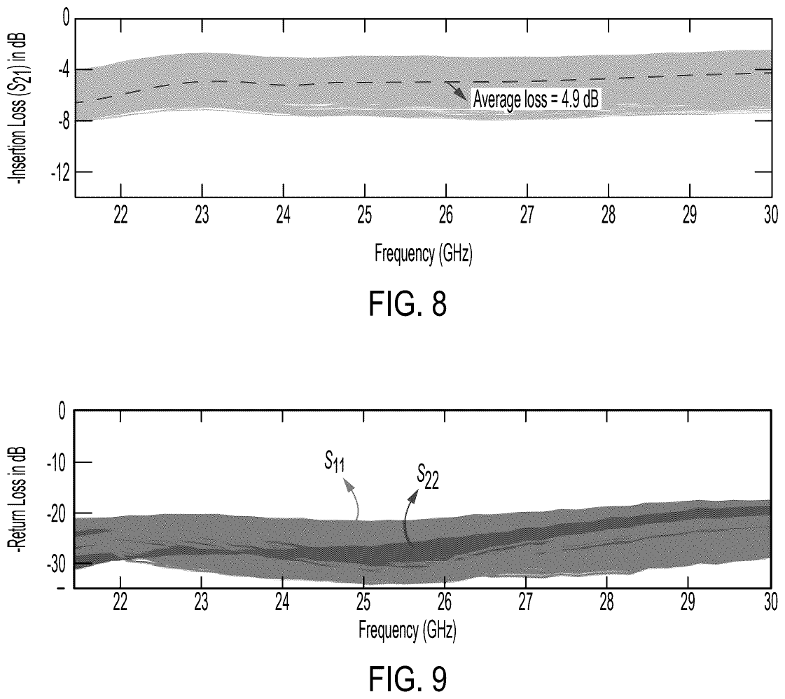

As shown in FIG. 8, loss through the phase shifter of FIG. 6 decreased with increasing frequency within the 20-30 GHz frequency band and, on average, was about 4.9 dB across the band. This contrasts with the conventional trend in high-frequency electronics and transmission line measurements wherein loss worsens at high frequency due to poor quality factors of switches and passive elements. This also confirms that the magnitudes of reflection coefficients of these loaded transmission lines progressively increase with frequency, as discussed above with reference to FIG. 4. FIG. 9 shows that the return loss (the percentage of signal reflected to the ports) exceeds 15 dB for every state of the phase shifter. This indicates that altering the reflective load has negligible effects on the coupler's coupling coefficients to its ports.

Since no analog-voltage-tuned varactor diodes were used in the illustrative embodiment of FIG. 6, the phase shifter's ability to reproduce the signal without harmonic distortion was boosted (far more than current microwave techniques). When measuring the power of intermodulation products across frequency and for high and low delay states, this phase shifter was found to have a power at which intermodulation products matched the power of the fundamental tone (an input referred IP₃) of over 25 dBm. This corresponds to a power at which the gain compresses by 1 dB (input referred P_{1 dB}) of over 15 dBm, higher than prior art CMOS phase shifters' signal linearity metrics.

The illustrative embodiment of FIG. 6 utilized a cutoff frequency around 20 GHz, allowing the resonant structures to handle signals in a 20-40 GHz post-resonance band, suitable for 5G MIMO beamsteering, satellite communication, and automotive radar signals, among other applications. It is contemplated other cutoff frequencies and post-resonance spectrums will be utilized in other embodiments according to the present disclosure. For instance, some embodiments may utilize a cutoff frequency around 500 MHZ, allowing the resonant structures to handle signals in a 1-6 GHz post-resonance band, suitable for WiFi and Bluetooth signals, among other applications. As another example, certain embodiments may utilize a cutoff frequency around 9 GHz, allowing the resonant structures to handle signals in a 10-22 GHz post-resonance band, suitable for satellite communication and defense radio (X-band) signals, among other applications. As yet another example, certain embodiments may utilize a cutoff frequency around 55 GHz, allowing the resonant structures to handle signals in a 60-85 GHz post-resonance band, suitable for mm-wave automotive radar signals, among other applications. As still another example, certain embodiments may utilize a cutoff frequency around 120 GHz, allowing the resonant structures to handle signals in a 140-300 GHz post-resonance band, suitable for beamsteering and phased arrays for high-resolution imaging (e.g., for airport scanners, medical imaging, etc.), among other applications. In some embodiments, the cutoff frequency is selected from a range of 500 MHz-120 GHz, including any value therewithin. In other embodiments, the cutoff frequency is below 500 MHz or above 120 GHz. The foregoing examples are merely illustrative and not restrictive in nature.

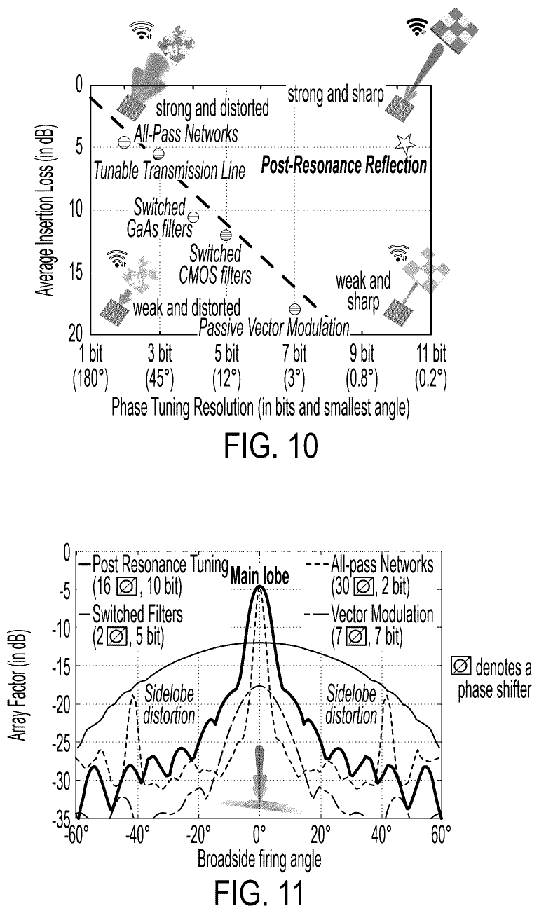

Since post-resonance tuning relegates the lossy resonances to lower frequencies, what lies higher than those is a broad, near-lossless band in which ultra-high-resolution phase-shift of under 0.2° is possible. As FIG. 10 illustrates, this scheme cleanly breaks the loss versus resolution trade-off of the prior art. In circuits, devices, systems, and methods according to the present disclosure, any loss is indifferent to the number of switches used.

A singular metric that clarifies the strength of various delay circuits for microwave communication is the Array Factor. It is the sum of individual phase shifters' contributions when they are arranged in an array. Array Factors for beams produced for three widely-used prior art approaches and for the presently disclosed post-resonance approach are compared in FIG. 11. Prior art all-pass networks are a class of broadband delay circuits in which one of a few options of fixed phase shifts is selected. They have low loss owing to few switches but are inherently coarse resolution devices. While, in principle, they may have small form-factors that result in good beam directivity, their coarse phase shift manifests itself as large sidelobes that heavily distort the radiated signal. Prior art switched-filters can be used to increase the bits of resolution, but they are composed of large capacitors and lossy inductors, meaning that only a couple of phase-shifters can be accommodated on a chip. Additionally, they are optimized for performance in the narrow frequency band around a resonance. These factors result in poor beam directivity in a target direction. Prior art Passive Vector Modulation techniques can increase the packing density in an array and, thus, increase phase resolution to seven bits of tuning (4° of phase resolution), but its insertion loss of over 15 dB is unacceptable for most practical applications. In contrast, as FIG. 11 also shows, the presently disclosed post-resonance approach not only accommodates sixteen elements within 1 mm² of chip area, but also gives a near-infinite resolution of ten bits to significantly suppress quantization noise and unwanted sidelobes. This produces the high signal-to-noise ratio needed to detect microwatt-level microwave signals in radio astronomy and for all types of radar. Notably, it achieves this with negligible insertion loss, which makes it the best candidate for beam steering in mobile communications and for precise phase-coupling between millimeter-wave antenna arrays.

While the disclosure has been illustrated and described in detail in the drawings and foregoing description, such an illustration and description is to be considered as illustrative and not restrictive in character, it being understood that only illustrative embodiments have been shown and described and that all changes and modifications that come within the spirit of the disclosure are desired to be protected.

There are a plurality of advantages of the present disclosure arising from the various features of the apparatus and methods described herein. It will be noted that alternative embodiments of the apparatus and methods of the present disclosure may not include all of the features described yet still benefit from at least some of the advantages of such features. Those of ordinary skill in the art may readily devise their own implementations of the apparatus and methods that incorporate one or more of the features of the present invention and fall within the spirit and scope of the present disclosure as defined by the appended claims.

1. A circuit comprising:
a first signal reflector comprising:
a first signal port configured to receive a signal in a signal frequency range used for communication or computation; and
a first resonant structure coupled between the first signal port and ground, the first resonant structure having (i) one or more primary resonances that interact to form one or more hybrid resonances and (ii) a cutoff frequency above resonant frequencies of the primary and hybrid resonances, wherein the cutoff frequency is below the signal frequency range.

2. The circuit of claim 1, wherein the first resonant structure is tunable to adjust the resonant frequencies.

3. The circuit of claim 2, wherein the first resonant structure comprises a segmented waveguide and tunable capacitances coupling each junction of the segmented waveguide to ground.

4. The circuit of claim 3, wherein each segmented waveguide includes at least three waveguide segments.

5. The circuit of claim 4, wherein each junction of the segmented waveguide is coupled to ground by a programmable capacitor bank comprising a plurality of parallel legs coupled between one junction of the segmented waveguide and ground, each of the plurality of parallel legs comprising a capacitor and a switch coupled in series.

6. The circuit of claim 3, wherein each tunable capacitance is digitally programmable.

7. The circuit of claim 3, further comprising vacatur diodes configured to tune the tunable capacitances.

8. The circuit of claim 3 implemented as an integrated circuit such that the first signal reflector has a sub-wavelength footprint.

9. The circuit of claim 8, wherein the segmented waveguide is formed as a conductive trace in an upper layer of the integrated circuit, and wherein each tunable capacitance is formed in lower layers of the integrated circuit.

10. The circuit of claim 1, further comprising:
a second signal reflector comprising (i) a second signal port configured to receive the signal in the signal frequency range and (ii) a second resonant structure coupled between the second signal port and ground, the second resonant structure having (i) one or more primary resonances that interact to form one or more hybrid resonances and (ii) a cutoff frequency above resonant frequencies of the primary and hybrid resonances, wherein the cutoff frequency is below the signal frequency range; and
a hybrid coupler having (i) an input port configured to receive the signal in the signal frequency range, (ii) a coupled port connected to the first signal port of the first signal reflector, (iii) a through port connected to the second signal port of the second signal reflector, and (iv) an output port configured to provide a phase-shifted copy of the signal.

11. The circuit of claim 10, wherein an amount of phase shift between the signal and the phase-shifted copy of the signal is controllable in increments of less than 1 degree with less than 10 dB of loss.

12. The phase shifter of claim 10, wherein an amount of phase shift between the signal and the phase-shifted copy of the signal is controllable in increments of less than 0.2 degrees with less than 5 dB of loss.

13. The phase shifter of claim 10, wherein the first signal reflector, the second signal reflector, and the hybrid coupler do not consume DC power.

14. The circuit of claim 10 implemented as an integrated circuit such that the first signal reflector, the second signal reflector, and the hybrid coupler have a sub-wavelength footprint.

15. A method comprising:
tuning resonant frequencies of a resonant structure coupled between a signal port and ground, wherein the resonant frequencies are associated with one or more primary resonances of the resonant structure that interact to form one or more hybrid resonances, and wherein the resonant structure has a cutoff frequency above the resonant frequencies; and
applying, to the signal port, a communication or computation input signal having a signal frequency above the cutoff frequency; and
receiving, at the signal port, a reflected signal with a phase shift relative to the communication or computation input signal, wherein the phase shift is a function of the resonant frequencies of the resonant structure.

16. The method of claim 10, wherein the resonant frequencies of the resonant structure are tunable to adjust the phase shift in increments of less than 1 degree with less than 10 dB of loss between the communication or computation input signal and the reflected signal.

17. The method of claim 10, wherein the resonant frequencies of the resonant structure are tunable to adjust the phase shift in increments of less than 0.2 degrees with less than 5 dB of loss between the communication or computation input signal and the reflected signal.

18. The method of claim 10, wherein the resonant structure comprises a segmented waveguide and tunable capacitances coupling each junction of the segmented waveguide to ground, and wherein tuning the resonant frequencies of the resonant structure comprises tuning one or more of the tunable capacitances.

19. The method of claim 18, wherein each of the tunable capacitances comprises a plurality of parallel legs coupled between one junction of the segmented waveguide and ground, each of the plurality of parallel legs comprising a capacitor and a switch coupled in series, and wherein tuning one or more of the tunable capacitances comprises switching one or more switches of the plurality of parallel legs.

20. The method of claim 18, wherein tuning one or more of the tunable capacitances comprises controlling one or more varactor diodes.
